(19) United States
(12) Patent Application Publication
(10) Pub. No.: US 2022/0015242 A1
(43) Pub. Date: Jan. 13, 2022

(54) APPARATUS AND METHOD FOR MANUFACTURING TRANSPARENT ELECTRODE

(71) Applicant: ITED INC., Daejeon (KR)

(72) Inventors: Jee-Hoon SEO, Namyangju-Si Gyeonggi-do (KR); Kum-Pyo YOO, Anseong-si, Gyeonggi-do (KR)

(21) Appl. No.: 17/293,354

(22) PCT Filed: Oct. 23, 2019
(86) PCT No.: PCT/KR2019/014017

§ 371 Date: May 12, 2021

(30) Foreign Application Priority Data
Nov. 15, 2018 (KR) 10-2018-0140558
Dec. 31, 2018 (KR) 10-2018-0173855

(51) Int. Cl. H05K 3/12; G01J 5/00

(52) U.S. Cl. CPC H05K 3/12; G01J 5/00; H05K 2203/163; G01J 2005/0077; H05K 2203/0147; G01J 2005/0081

(57) ABSTRACT

This application relates to an apparatus and method for manufacturing a transparent electrode. One surface of a base substrate is surface-treated with a predetermined material or predetermined light. A conductive material and a hydrophilic solution are sprayed onto the surface-processed base substrate by using a spray block including a spray nozzle and a thermographic camera. The conductive solution is sprayed onto the processed base substrate to form a surface heating body. The surface heating body is heated to be photographed by the thermographic camera. A controller analyzes a photographed image to define an area of supplementation and form a supplemented surface heating body in the area of supplementation by using the spray nozzle, and thus a transparent electrode having uniform heating characteristics is manufactured.

### BACKGROUND

### 1. Technical Field

The present disclosure relates to an apparatus and a method for forming a transparent electrode having uniform heating characteristics even on a curved substrate or a substrate containing a hydrophobic material.

### 2. Description of the Related Art

Unlike the conventional, colored surface heating body, a colorless, transparent surface heating body may be used with a glass, such as a windshield of an automobile or an aircraft, a CCTV camera lens, etc., to prevent and/or remove fog or frost formed on the glass by generating the heat.

However, if the surface heating body has a surface of which a portion is protruded, it has been difficult to manufacture the surface heating body to have uniform temperature characteristics and to uniformly spread a conductive material throughout a base substrate during the manufacturing process.

### SUMMARY OF THE INVENTION

An object of the present disclosure is to provide a transparent electrode and a transparent heating body having uniform heating characteristics.

An apparatus for manufacturing a transparent electrode may include a substrate support, a substrate mover, a surface treatment device, a first spray block including a housing having a spray nozzle and a thermographic camera received therein, s power module including an electrode and a power source, and a control module configured to control the substrate mover, the surface treatment device, the spray block, and the power module.

The substrate support may be configured for supporting a base substrate including a hydrophobic material. The substrate mover may be configured to move the substrate support on a plane

The surface treatment device may be configured to form a processed base substrate by providing a predetermined material or predetermined light to the base substrate.

The spray nozzle may be configured to spray a conductive material and a hydrophilic solution onto the processed base substrate to form a surface heating body.

The power module may be configured to supply electric power to the surface heating body.

The thermographic camera may be configured to photograph heat generated from the surface heating body supplied with the electric power

The control module may be configured to analyze the heat photographed by the thermographic camera to define an area of supplementation by determining a portion of the surface heating body that has a lower temperature than other portions of the surface heating body.

The spray block may form a supplemented surface heating body in the area of supplementation.

The apparatus for manufacturing a transparent electrode in accordance with an embodiment of the present disclosure may further include a second spray block. The second spray block may be separated from the first spray block and may include a second spray nozzle configured to spray a conductive material and a hydrophilic solution onto the base substrate to form a supplemented surface heating body.

In an embodiment of the present disclosure, the second spray block may be configured to form the supplemented surface heating body in the defined area of supplementation.

In an embodiment of the present disclosure, the second spray block may include a second thermographic camera.

In an embodiment of the present disclosure, the surface treatment device may be configured to not move on the plane, and the base substrate may be configured to be moved on the plane by the substrate mover.

In an embodiment of the present disclosure, when the first spray block sprays the conductive material and the hydrophilic solution, the first spray block may be configured to not move on the plane, and the base substrate may be configured to be moved on the plane by the substrate mover.

In an embodiment of the present disclosure, the predetermined light may be ultraviolet (UV) light.

In an embodiment of the present disclosure, the predetermined material may include oxygen plasma.

In an embodiment of the present disclosure, the base substrate may include a first busbar and a second busbar separated from the first busbar. The surface heating body may be disposed on the base substrate, the first busbar and the second busbar, and the first electrode may be electrically connected to the first busbar, and the second electrode may be electrically connected to the second busbar, to transfer the electric power.

In an embodiment of the present disclosure, the first electrode and the second electrode may each have a rod shape.

In an embodiment of the present disclosure, the first electrode and the second electrode may each be capable of being in contact with and separated from a top surface of the surface heating body.

In an embodiment of the present disclosure, the base substrate may include glass.

In an embodiment of the present disclosure, the base substrate may include a granite plate.

A method of manufacturing a transparent electrode in accordance with an embodiment of the present disclosure may include: preparing a base substrate; processing a surface of the base substrate by surface-treating one surface of the base substrate; forming a surface heating body by coating silver nanowire onto the processed one surface of the base substrate; generating heat by supplying electric power to the surface heating body; photographing the generated heat by use of a thermographic camera; analyzing, by a control module, the photographed heat to define an area of ununiformly coated silver nanowire as an area of supplementation; and additionally coating, by a spray block, the defined area of supplementation.

In an embodiment of the present disclosure, the step of preparing the base substrate may include disposing a first busbar and a second busbar on the base substrate, the second busbar being separated from the first busbar.

According to an embodiment of the present disclosure, as the base substrate is changed from being hydrophobic to being hydrophilic, the adhesiveness between the base substrate and the coating material may be enhanced, and the uniformity of coating may be enhanced.

Moreover, according to an embodiment of the present disclosure, a transparent surface heating body having a uniform temperature property may be manufactured through the step of secondarily coating an area of low heat after the primary coating.

### BRIEF DESCRIPTION OF THE DRAWINGS

FIG. 1 illustrates an apparatus for manufacturing a transparent electrode in accordance with an embodiment of the present disclosure.

FIG. 2A is an example illustration of supplying electric power to a base substrate including a first busbar and a second busbar.

FIG. 2B is an example illustration of supplying electric power to a base substrate including no busbar.

FIG. 3 is an example illustration of a base substrate of which the surface is processed.

FIG. 4 is an example illustration of a transparent heating body formed by having a solution containing a conductive material sprayed over the processed base substrate shown in FIG. 3.

FIG. 5 is an example illustration of the heat being generated from the surface heating body by the electric power supplied to the coated surface heating body shown in FIG. 6.

FIG. 6 is an example illustration of having the heat shown in FIG. 5 photographed by a thermographic camera and additionally coating a supplemented surface heating body in an area of the base substrate where the heating is not uniform.

FIG. 7 is an example illustration of supplying electric power to a silver nanowire additionally coated as shown in FIG. 6 and exhibiting uniform heating characteristics.

FIG. 8 illustrates an example apparatus for manufacturing a transparent electrode in accordance with an embodiment of the present disclosure.

FIG. 9 is a flow diagram showing a method of manufacturing a transparent electrode in accordance with an embodiment of the present disclosure.

### DETAILED DESCRIPTION

Hereinafter, certain embodiments of the present disclosure will be described with reference to the accompanying drawings.

In the illustrated drawings, the scales and dimensions of the elements may be exaggerated for an effective description of the technical details of the present disclosure. When certain configurations are joined by “and/or,” all of one or more combinations that may be defined by these configurations may be encompassed.

Terms such as “comprise,” “include,” etc. are intended to specify the presence of features, numbers, steps, actions, elements, components or combinations thereof described in the specification and are not intended to preclude the possible presence or addition of one or more other features, numbers, steps, actions, elements, components or combinations thereof.

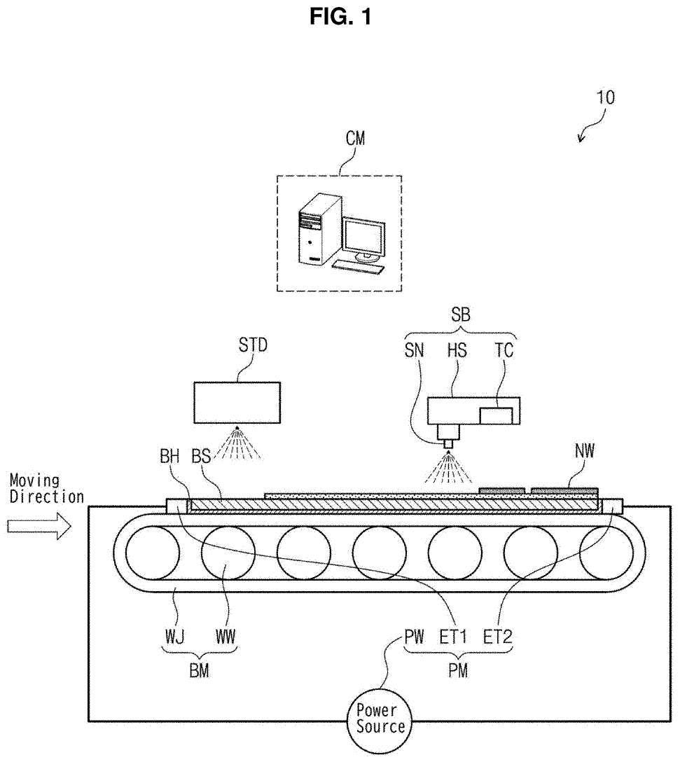

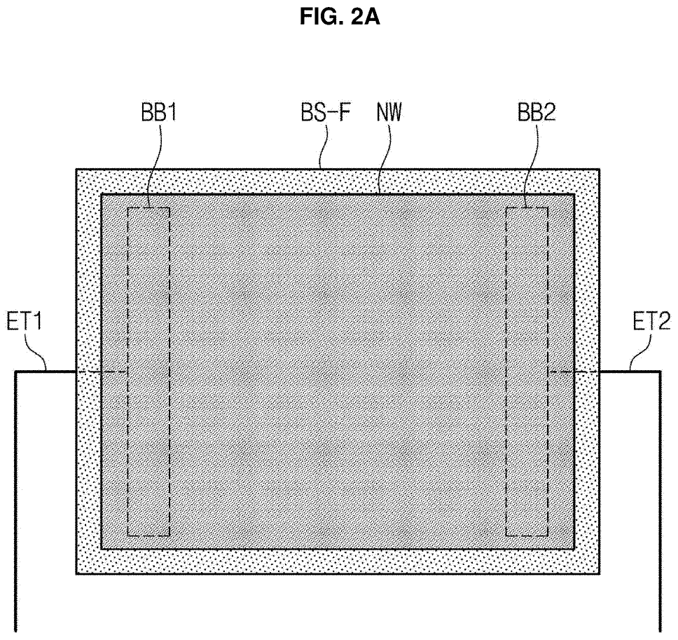

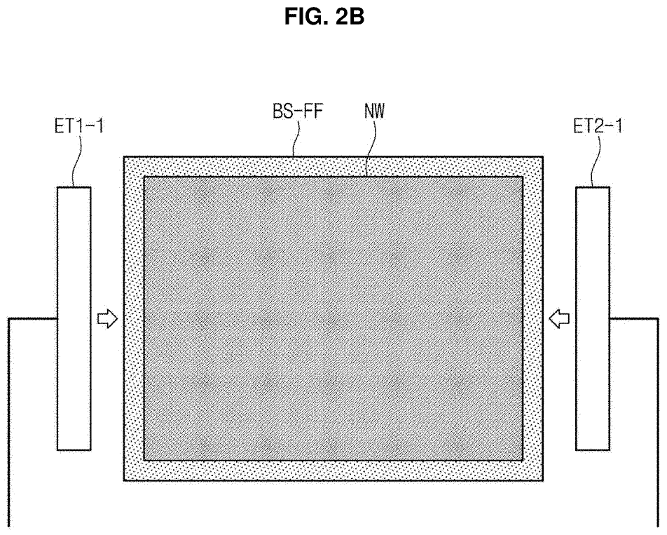

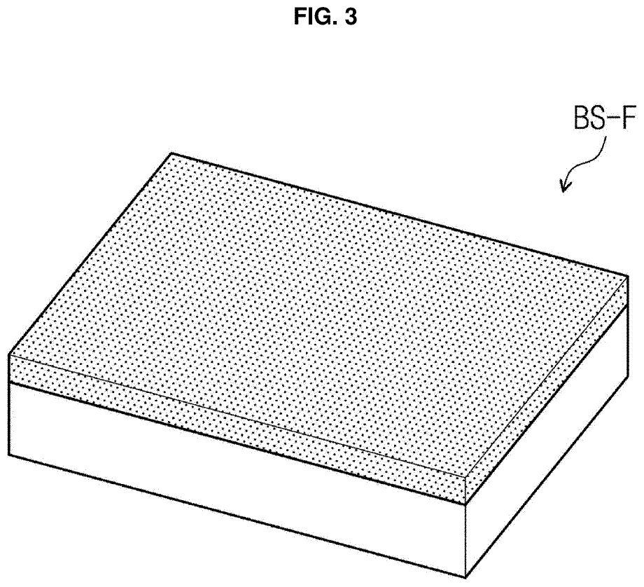

FIG. 1 illustrates an apparatus 10 for manufacturing a transparent electrode in accordance with an embodiment of the present disclosure. FIG. 2A is an example illustration of supplying electric power to a base substrate BS including a first busbar BB1 and a second busbar BB2. FIG. 2B is an example illustration of supplying electric power to a base substrate BS including no busbar. FIG. 3 is an example illustration of a processed base substrate BS-F.

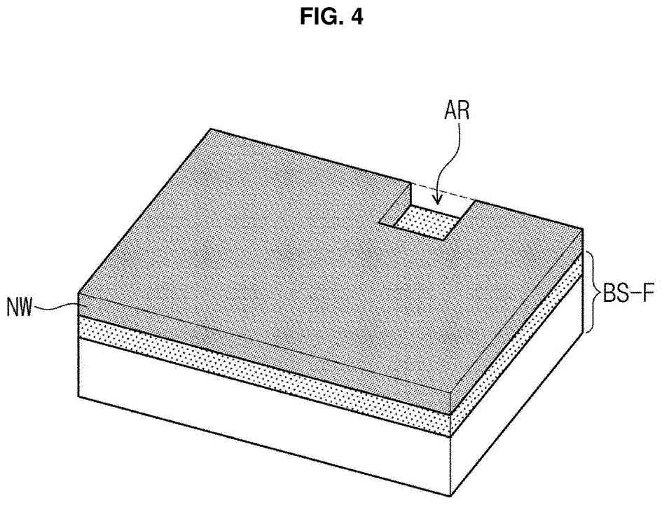

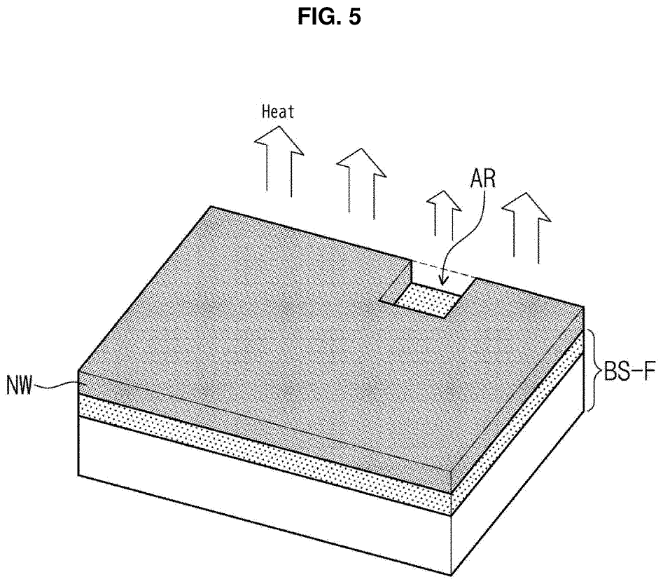

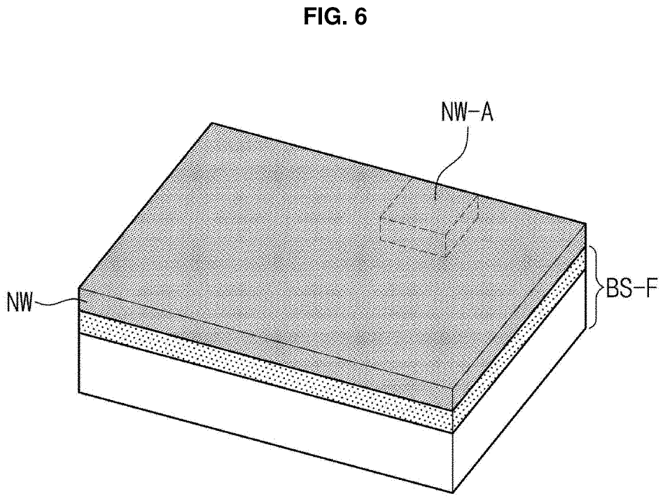

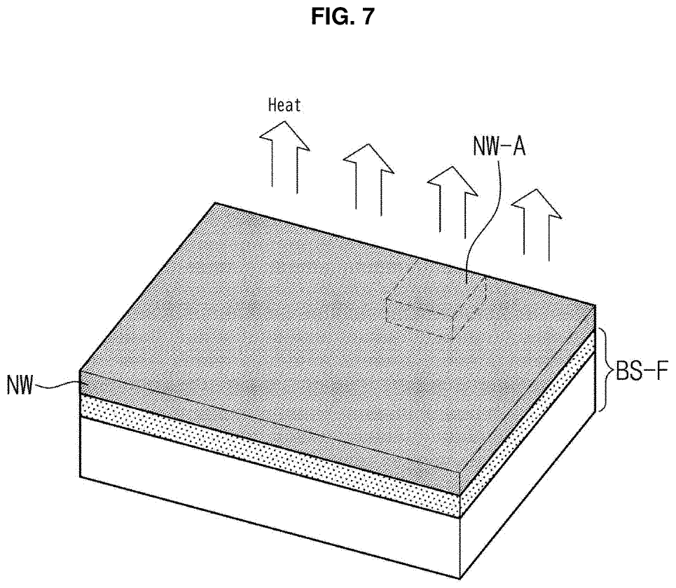

FIG. 4 is an example illustration of a transparent heating body NW formed by having a solution containing a conductive material sprayed over the processed base substrate BS-F shown in FIG. 3. FIG. 5 is an example illustration of the heat being generated from the surface heating body NW to which the electric power is supplied. FIG. 6 is an example illustration of having the heat shown in FIG. 5 photographed by a thermographic camera TC and additionally coating a supplemented surface heating body NW-A in an area of supplementation AR. FIG. 7 is an example illustration of supplying electric power to the additionally coated surface heating body NW and exhibiting uniform heating characteristics.

Referring to FIG. 1, the apparatus 10 for manufacturing a transparent electrode may include a substrate support BH, a substrate mover BM, a surface treatment device STD, a spray block SB, a power module PM and a control module CM.

The substrate support BH may provide a supporting surface to the base substrate BS, which may include glass or granite plate. The base substrate BS may include a hydrophobic material.

The substrate mover BM may include a substrate mover jig WJ and a substrate mover power supply WW. The substrate mover jig WJ may include a conveyer belt.

In an embodiment of the present disclosure, the substrate support BH may be included in the substrate mover jig WJ.

According to an embodiment of the present disclosure, the substrate support BH may be separately positioned over the substrate mover jig WJ to move in one direction along the substrate mover BM.

The surface treatment device STD may provide a predetermined material or predetermined light to one surface of the base substrate BS.

Referring to FIG. 3, the one surface of the base substrate BS provided with the predetermined material or the predetermined light by the surface treatment device STD may become hydrophilic from hydrophobic, thereby forming the processed base substrate BS-F.

According to an embodiment of the present disclosure, the predetermined material may be a material containing oxygen plasma. According to an embodiment of the present disclosure, the predetermined light may be an ultraviolet (UV) light.

The spray block SB may include a spray nozzle SN, a thermographic camera TC and a housing HS, which receives therein at least a portion of the spray nozzle SN and at least a portion of the thermographic camera TC.

The spray block SB may move on a plane.

The spray nozzle SN may be configured to spray a conductive material and a hydrophilic solution onto one surface of the processed based substrate BS-F. In an embodiment of the present disclosure, the spray nozzle SN spraying the conductive material and the hydrophilic solution may be understood as coating the conductive material on the processed base substrate BS-F.

In an embodiment of the present disclosure, the conductive material may be, but not limited to, AgNW, ITO or IZO, or any other material sufficient for forming a transparent electrode.

In an embodiment, the hydrophilic solution may be, but not limited to, water, ethanol or methanol.

The base substrate BS that is not processed by the surface treatment device STD is hydrophobic. Accordingly, if the conductive material is coated on the unprocessed base substrate BS, a surface energy becomes different between the base substrate BS and the hydrophilic solution. As a result, the conductive material is caused to lump after the coating, and the coating becomes less uniform, thereby preventing the surface heating body from heating uniformly. However, by coating the processed base substrate BS-F, the adhesiveness of the coating material and the coating uniformity may be enhanced.

The processed base substrate BS-F is sprayed with the conductive material and the hydrophilic solution to form a surface heating body NW that is transparent.

Referring to FIG. 6, silver nanowire NW may uniformly coated over the processed base substrate BS-F to form the surface heating body NW.

The power module PM may include a first electrode ET1, a second electrode ET2 and a power source PW.

The power module PM may provide electric power to the surface heating body NW.

Referring to FIG. 2A, in an embodiment of the present disclosure, the processed base substrate BS-F may include a first busbar BB1 and a second busbar BB2. The first electrode ET1 and the second electrode ET2 may be in contact with the first busbar BB1 and the second busbar BB2, respectively, to transfer the electric power provided by the power source PW to surface heating body NW. The first electrode ET1 and the second electrode ET2 may be in contact with and separated from the first busbar BB1 and the second busbar BB2, respectively.

Referring to FIG. 2B, in an embodiment of the present disclosure, a processed base substrate BS-FF may not include any busbar. A first electrode ET1-1 and a second electrode ET2-1 may be in contact with a top surface of the surface heating body NW to transfer the electric power provided by the power source PW and then may be separated from the top surface of the surface heating body NW. The first electrode ET1-1 and the second electrode ET2-1 may each be a printed circuit board (PCB) or metal wiring having an elongated cuboid bar shape (or a rod shape).

The surface heating body NW supplied with the electric power may generate heat.

Referring to FIG. 4, the coated surface heating body NW may be supplied with electric power to generate heat.

The thermographic camera TC may be configured to photograph the generated heat. The control module CM may be configured to analyze an image photographed by the thermographic camera TC to define a portion having a relatively smaller amount of the generated heat than other portions as an area of supplementation AR. That is, the area of supplementation AR is defined an area where the surface heating body NW is relatively poorly formed, as compared to other portions.

Referring to FIG. 4 and FIG. 5, the silver nanowire may be ununiformly sprayed over the processed base substrate BS-F to form an ununiform surface heating body NW. Electric power may be supplied by the power module PM to the ununiformly formed surface heating body NW to generate heat.

Referring to FIG. 6, the spray nozzle SN may spray the conductive material and the hydrophilic solution to the area of supplementation AR to form a supplemented surface heating body NW-A.

The thermographic camera TC or a second thermographic camera TC2 may be configured to photograph the generated heat, and the control module CM may be configured to verify the uniformity of the coating.

Referring to FIG. 7, the supplemented surface heating body NW, NW-A may have unform heating characteristics.

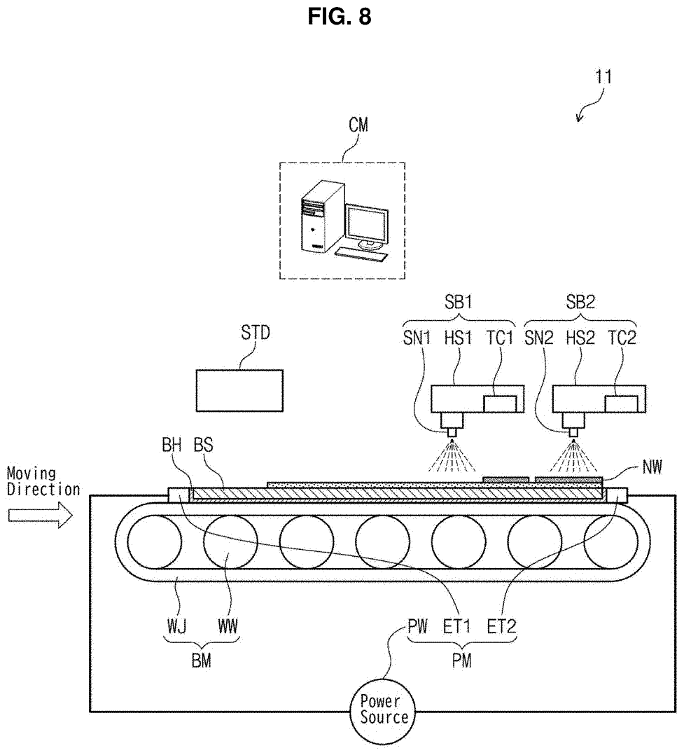

FIG. 8 illustrates an example apparatus 11 for manufacturing a transparent electrode in accordance with an embodiment of the present disclosure.

Referring to FIG. 8, the apparatus 11 for manufacturing a transparent electrode may include a substrate support BH, a substrate mover BM, a surface treatment device STD, a first spray block SB1, a second spray block SB2, a power module PM and a control module CM.

The first spray block SB1 may include a first spray nozzle SN1, a first thermographic camera TC1, which is adjacent to the first spray nozzle SN1, and a first housing HS1, which receives therein at least a portion of the first spray nozzle SN1 and at least a portion of the first thermographic camera TC1.

The first spray block SB1 is configured to use the first spray nozzle SN1 to spray a conductive material and a hydrophilic solution onto a processed base substrate BS-F to form a surface heating body NW. The first thermographic camera TC1 is configured to photograph the heat generated from the surface heating body NW. The second spray block SB2 may include a second spray nozzle SN2, a second thermographic camera TC2, which is adjacent to the second spray nozzle SN2, and a second housing HS2, which receives therein at least a portion of the second spray nozzle SN2 and at least a portion of the second thermographic camera TC2.

The second spray block SB2 may be configured to additionally spray silver nanowire to an area of supplementation AR, defined by the control module CM, to form a supplemented surface heating body NW-A. The second thermographic camera TC2 may be configured to photograph the heat generated from the supplemented surface heating body NW-A.

Other configurations of FIG. 8 are substantially identical with the configurations described with reference to FIG. 1 to FIG. 7 and thus will not be described redundantly.

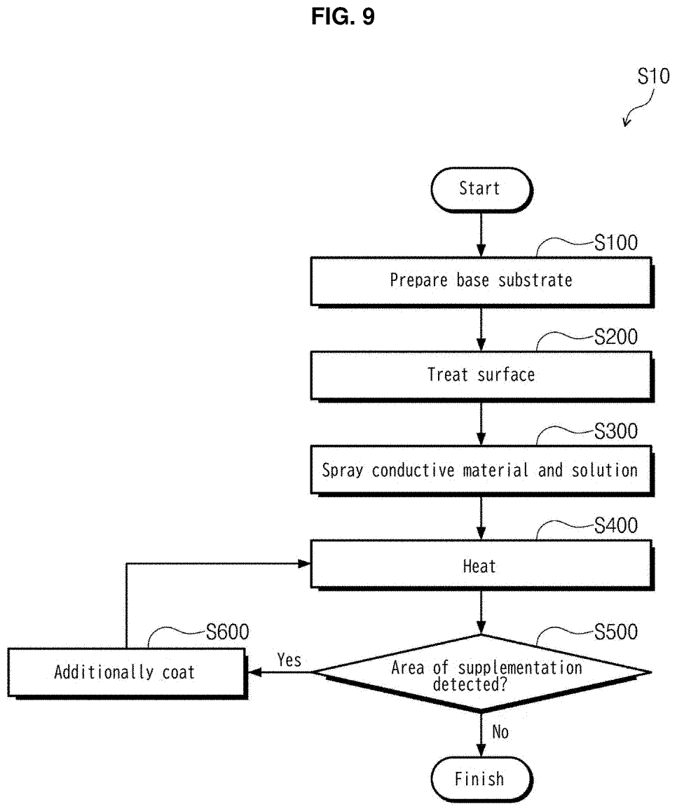

FIG. 9 is a flow diagram for a method S10 of manufacturing a transparent electrode in accordance with an embodiment of the present disclosure.

Referring to FIG. 9, the method S10 of manufacturing a transparent electrode may include: preparing a base substrate (S100); treating a surface (S200); spraying a conductive material and solution (S300); heating (S400); sensing, by a thermographic camera TC, the generated heat and measuring a uniformity of coating (S500); detecting an area of supplementation (S600); and additionally coating (S700).

Referring to FIG. 2A, in an embodiment of the present disclosure, the step of preparing the base substrate (S100) may include forming busbars BB1, BB2 in the base substrate BS.

In the step of treating the surface (S200), the base substrate BS, which is hydrophobic, may be processed by a surface treatment device STD to become hydrophilic.

In the step of spraying the conductive material and solution (S300), silver nanowire may be sprayed to a processed base substrate BS-F to form a surface heating body NW.

In the step of heating (S400), electric power may be supplied to the formed surface heating body NW to generate the heat. In the step of detecting the area of supplementation (S600), the thermographic camera TC may photograph the heat generated from the surface heating body NW, and a control module CM may analyze the photographed heat to define an area of supplementation AR.

In the step of additionally coating (S600), in the case where there is the area of supplementation AR, a spray nozzle (e.g., SN in FIG. 1) or a second spray nozzle (e.g., SN2 in FIG. 8) may form a supplemented surface heating body NW-A in the area of supplementation AR.

While certain embodiments of the present disclosure have been described, it shall be appreciated that the described embodiments are exemplary only and that the present disclosure is by no means limited to the described embodiments. Anyone of ordinary skill in the art to which the present disclosure pertains will readily be able to modify or vary the described embodiments by means of supplementing, modifying, deleting or adding one or more elements of the present disclosure within the scope of the present disclosure, as defined by the appended claims, and such supplementation, modification, deletion or addition shall be deemed to be within the scope of the present disclosure.

### INDUSTRIAL APPLICABILITY

Unforming heating a target object by use of a surface heating body is particularly important. The present disclosure may provide a transparent electrode and a transparent heating body having uniform heating characteristics and thus is highly industrially applicable.

1. An apparatus for manufacturing a transparent electrode, comprising:
a substrate support configured to support a base substrate including a hydrophobic material;
a substrate mover configured to move the substrate support on a plane;
a surface treatment device configured to convert a surface of the base substrate to become hydrophilic by providing predetermined light or a predetermined material to the surface of the base substrate;
a first spray block comprising a spray nozzle configured to spray a conductive material and a hydrophilic solution onto the base substrate to form a surface heating body, a thermographic camera, and a housing having the spray nozzle and the thermographic camera received therein;
a power module comprising a first electrode, a second electrode separated from the first electrode, and a power source configured to supply electric power to the first electrode and the second electrode, the first electrode and the second electrode being configured to transfer the electric power supplied by the power source to the surface heating body formed on the base substrate; and
a controller configured to control the substrate mover, the surface treatment device, the first spray block, and the power module,
wherein the thermographic camera is configured to photograph the surface heating body heated by receiving the electric power, and
wherein the controller is configured to analyze an image photographed by the thermographic camera to define an area of supplementation by determining a portion of the surface heating body that has a lower temperature than other portions of the surface heating body.

2. The apparatus of claim 1, further comprising a second spray block separated from the first spray block and comprising a second spray nozzle configured to spray a conductive material and a hydrophilic solution onto the base substrate to form a supplemented surface heating body.

3. The apparatus of claim 2, wherein the second spray block is configured to form the supplemented surface heating body in the area of supplementation defined in the surface heating body.

4. The apparatus of claim 2, wherein the second spray block further comprises a second thermographic camera.

5. The apparatus of claim 1, wherein the first spray block is configured to additionally spray the conductive material and the hydrophilic solution onto the area of supplementation defined in the surface heating body.

6. The apparatus of claim 2, wherein the surface treatment device is configured to not move on the plane, and the base substrate is configured to be moved on the plane by the substrate mover.

7. The apparatus of claim 1, wherein, when the first spray block sprays the conductive material and the hydrophilic solution, the first spray block is configured to not move on the plane, and the base substrate is configured to be moved on the plane by the substrate mover.

8. The apparatus of claim 1, wherein the predetermined light is ultraviolet (UV) light.

9. The apparatus of claim 1, wherein the predetermined material comprises oxygen plasma.

10. The apparatus of claim 1, wherein the base substrate comprises:
a first busbar disposed on the base substrate; and
a second busbar disposed on the base substrate and separated from the first busbar,
wherein the surface heating body is disposed on the base substrate, the first busbar and the second busbar,
wherein the first electrode is electrically connected to the first busbar, and
wherein the second electrode is electrically connected to the second busbar.

11. The apparatus of claim 1, wherein each of the first electrode and the second electrode has a rod shape.

12. The apparatus of claim 11, wherein each of the first electrode and the second electrode is configured to be in contact with and separated from a top surface of the surface heating body.

13. The apparatus of claim 1, wherein the base substrate comprises glass.

14. The apparatus of claim 1, wherein the base substrate comprises a granite plate.

15. A method of manufacturing a transparent electrode, comprising:
preparing a base substrate;
treating a surface by providing a predetermined material or predetermined light onto one surface of the base substrate to form a processed base substrate;
forming a surface heating body on the processed base substrate by spraying a conductive material and a hydrophilic solution onto the processed base substrate;
generating heat from the surface heating body by supplying electric power to a first side of the surface heating body and a second side of the surface heating body separated from the first side;
photographing, by a thermographic camera, the generated heat;
analyzing the photographed heat to define as an area of supplementation by determining a portion of the surface heating body that has a lower temperature than other portions of the surface heating body; and
additionally forming a supplemented surface heating body in the area of supplementation.

16. The method of claim 15, wherein each of a first electrode configured to supply the electric power to the first side and a second electrode configured to supply the electric power to the second side has a rod shape, and
wherein the generating comprises contacting the first electrode and the second electrode with the surface heating body and heating the surface heating body.

17. The method of claim 15, wherein the predetermined material comprises oxygen plasma.

18. The method of claim 15, wherein the predetermined light is ultraviolet (UV) light.

19. The method of claim 15, wherein the preparing comprises disposing a first busbar and a second busbar on the base substrate, the second busbar being separated from the first busbar.

20. The method of claim 19, wherein the generating comprises transferring, by the first busbar, the electric power to the first side and transferring, by the second busbar, the electric power to the second side.
